(19) United States
(12) Patent Application Publication
(10) Pub. No.: US 2018/0061463 A1
(43) Pub. Date: Mar. 1, 2018

(54) PRE-CHARGE CIRCUIT FOR PREVENTING INRUSH CURRENT AND ELECTRONIC DEVICE INCLUDING THE SAME

(71) Applicant: Samsung Electronics Co., Ltd., Suwon-si (KR)

(72) Inventors: Ik-sung PARK, Hwaseong-si (KR); Joo-young KIM, Suwon-si (KR); Hee-youb KANG, Seoul (KR); Kwan-bin YIM, Yongin-si (KR); Byung-yun CHO, Suwon-si (KR)

(73) Assignee: Samsung Electronics Co., Ltd., Suwon-si, (KR)

(21) Appl. No.: 15/490,353

(22) Filed: Apr. 18, 2017

(30) Foreign Application Priority Data
Aug. 29, 2016 (KR) 10-2016-0110093

(51) Int. Cl. G11C 7/12; G11C 8/08; H01L 23/538; G05F 1/565

(52) U.S. Cl. CPC G11C 7/12; G11C 8/08; G05F 1/565; H01L 23/5386; H01L 23/5383; H01L 23/5384

(57) ABSTRACT

An electronic device includes a power connector, a power supply conductive line, and a pre-charge conductive line. The power connector includes a pre-charge pin and a power supply pin. The power supply conductive line has a first resistance, and is configured to electrically connect the power supply pin to a power supply node. The pre-charge conductive line has a second resistance, which is greater than the first resistance, and the pre-charge conductive line is configured to electrically connect the pre-charge pin to the power supply node without an intervening resistor between the pre-charge pin and the power supply node.

### CROSS-REFERENCE TO RELATED APPLICATION(S)

This application claims priority under 35 U.S.C. §119 to Korean Patent Application No. 10-2016-0110093, filed on Aug. 29, 2016, in the Korean Intellectual Property Office, the disclosure of which is incorporated herein in its entirety by reference.

### BACKGROUND

### Field

At least some example embodiments relate to pre-charge circuits and/or electronic devices including the same, and more particularly, to pre-charge circuits configured to suppress inrush currents and/or electronic devices including the same.

### Description of Related Art

An electronic device may include a pre-charge circuit, which further includes a resistor element. During a hot plug operation to connect an electronic device to an external power source, for example, the pre-charge circuit may prevent inrush currents from being generated in the electronic device. However, resistor elements of pre-charge circuits may occupy relatively large mounting space on a circuit substrate, and thus, may hinder miniaturization of electronic devices.

### SUMMARY

One or more example embodiments provide pre-charge circuits configured to more effectively suppress and/or prevent inrush currents, and/or further reduce sizes of electronic devices. One or more example embodiments also provide electronic devices including pre-charge circuits configured to more effectively suppress and/or prevent inrush currents, and/or further reduce sizes of electronic devices.

At least one example embodiment provides an electronic device comprising: a plurality of semiconductor devices; a connector including a pre-charge pin and a power pin; a pre-charge conductive line configured to electrically connect the pre-charge pin to a voltage supply node, the pre-charge conductive line having a first resistance value configured to generate pre-charge current for a pre-charge operation on the plurality of semiconductor devices, the pre-charge current performed to prevent inrush currents due to an external power source; a first conductive line having a second resistance value, the first conductive line configured to electrically connect the power pin to the voltage supply node, and to transmit a power voltage to the voltage supply node from the external power source, the second resistance value less than the first resistance value; and a second conductive line configured to electrically connect the plurality of semiconductor devices to the voltage supply node, and to transmit the power voltage to the plurality of semiconductor devices.

At least one other example embodiment provides a pre-charge circuit, comprising: a first pre-charge pin electrically connected to a first external power source; a second pre-charge pin electrically connected to a second external power source; a first pre-charge conductive line configured to electrically connect the first pre-charge pin to a first voltage supply node, the first pre-charge conductive line having a first resistance value configured to generate first pre-charge current for a first pre-charge operation on at least one first semiconductor device receiving a first power voltage via the first voltage supply node; and a second pre-charge conductive line configured to electrically connect the second pre-charge pin to a second voltage supply node, the second pre-charge conductive line having a second resistance value to generate second pre-charge current for a second pre-charge operation on at least one second semiconductor device receiving a second power voltage via the second voltage supply node.

At least one other example embodiment provides an electronic device comprising: a power connector; a power supply conductive line; and a pre-charge conductive line. The power connector includes a pre-charge pin and a power supply pin. The power supply conductive line has a first resistance, and is configured to electrically connect the power supply pin to a power supply node. The pre-charge conductive line has a second resistance, which is greater than the first resistance, and the pre-charge conductive line is configured to electrically connect the pre-charge pin to the power supply node without an intervening resistor between the pre-charge pin and the power supply node.

### BRIEF DESCRIPTION OF THE DRAWINGS

At least some example embodiments of inventive concepts will be more clearly understood from the following detailed description taken in conjunction with the accompanying drawings in which:

FIG. 1 is a block diagram schematically showing a user device according to an example embodiment;

FIG. 2 is a diagram showing, in more detail, a power connector and a power voltage transmitter of an electronic device, according to an example embodiment;

FIGS. 3A and 3B are diagrams showing more detailed structures of power voltage transmitters of electronic devices, according to example embodiments;

FIG. 4 is a diagram showing a more detailed structure of a power voltage transmitter of an electronic device, according to another example embodiment;

FIG. 5 is a diagram showing a more detailed structure of a power voltage transmitter of an electronic device, according to another example embodiment;

FIGS. 6A through 6B are three-dimensional views of circuit substrates included in an electronic device, according to an example embodiment;

FIG. 7 is a cross-sectional view of a multi-layered circuit substrate included in an electronic device, according to another example embodiment;

FIGS. 8A and 8B are cross-sectional views of multi-layered circuit substrates included in an electronic device, according to another example embodiment;

FIG. 9 is a diagram of a power connector included in an electronic device, according to an example embodiment;

FIG. 10 is a diagram showing, in more detail, a power connector and a power voltage transmitter of an electronic device, according to another example embodiment;

FIGS. 11A through 11C are diagrams showing more detailed structures of power voltage transmitters of electronic devices, according to example embodiments;

FIG. 12 is a diagram showing a more detailed structure of a power voltage transmitter of an electronic device, according to another example embodiment;

FIG. 13 is a diagram showing a more detailed structure of a power voltage transmitter of an electronic device, according to another example embodiment;

FIG. 14 is a flowchart of a method of forming a pre-charge conductive line on a circuit substrate, according to an example embodiment; and

FIG. 15 is a block diagram showing an example data storage device according to an example embodiment.

### DETAILED DESCRIPTION

Hereinafter, example embodiments of inventive concepts will be described in detail by referring to the accompanying drawings. Expressions such as “at least one of,” when preceding a list of elements, modify the entire list of elements and do not modify the individual elements of the list.

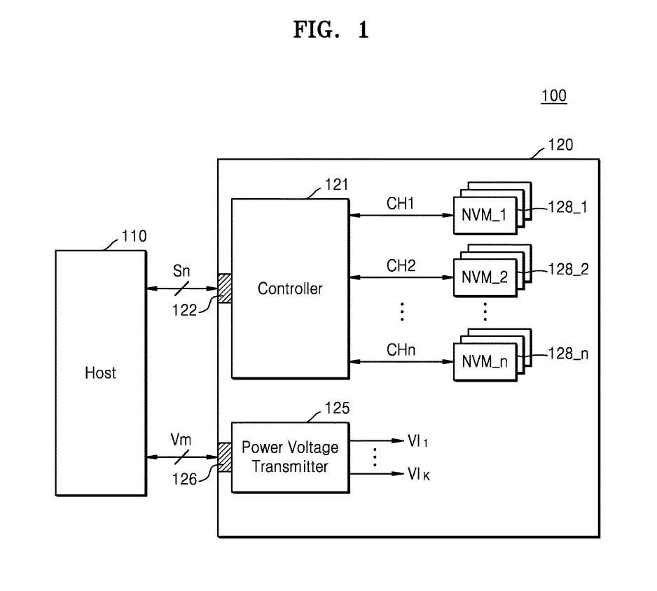

FIG. 1 is a block diagram schematically showing a user device 100 according to an example embodiment.

Referring to FIG. 1, the user device 100 may include a host 110 and an electronic device 120. The electronic device 120 according to an example embodiment may refer to a device operating by receiving a power supply from another device, such as the host 110. For example, the electronic device 120 may be a data storage device. Hereinafter, descriptions will be made by assuming that the electronic device 120 is a data storage device. However, it is only an example embodiment, and inventive concepts may be applied to all electronic devices 120 operating by using a power supply received from another device. For example, the data storage device 120 may be included in a semiconductor disk device (e.g., a solid state disk or a solid state drive, hereinafter, referred to as an SSD). However, it is only an example to which inventive concepts are applied, and the data storage device 120 according to example embodiments is not limited to an SSD, and may have various other forms. For example, the data storage device 120 may be integrated into a semiconductor device, and may be included in a PC card (personal computer memory card international association (PCMCIA) card), a compact flash card, a smart media card, a memory stick, a multimedia card, an SD card (micro SD), a universal flash storage, etc.

The host 110 may be configured to control the data storage device 120. The host 110 may include a portable device, such as a smart phone, a personal/portable computer, a personal digital assistant (PDA), a portable media player (PMP), an MP3 player, etc. The host 110 and the data storage device 120 may be connected via a standardized interface, such as universal serial bus (USB), small computer system interface (SCSI), enhanced small device interface (ESDI), serial advanced technology attachment (SATA), single attachment station (SAS), PCI-express, or integrated device electronics (IDE). The interface for connecting the host 110 and the data storage device 120 is not limited to a particular form, and may include various forms.

The data storage device 120 may include a controller 121, a signal connector 122, a power voltage transmitter 125, a power connector 126, and a plurality of non-volatile memories (NVM_1, NVM_2, . . . , NVM_n) 128_1 through 128_n. According to an example embodiment, the signal connector 122 and the power connector 126 may correspond to the interface standards between the data storage device 120 and the host 110. Each of the controller 121 and the non-volatile memories 128_1 through 128_n may include at least one semiconductor device. The non-volatile memories 128_1 through 128_n included in the data storage device 120 may store data received from the host 110. A flash memory (e.g., a NAND flash memory device or vertical NAND (VNAND) flash memory device) may be used to realize the non-volatile memories 128_1 through 128_n. In addition to the flash memory, phase-change random access memory (PRAM), magnetic random access memory (MRAM), resistive random access memory (ReRAM), ferroelectric random access memory (FRAM), etc. may be used to realize the non-volatile memories 128_1 through 128_n. Also, volatile memory, such as dynamic random access memory (DRAM) or static random access memory (SRAM), or hybrid memory including at least two types of memories may be used to realize the non-volatile memories 128_1 through 128_n. The non-volatile memories 128_1 through 128_n may be connected to the controller 121 via a plurality of channels CH1 through CHn. One or more non-volatile memories may be connected to one channel, and the non-volatile memories connected to one channel may be connected to the same data bus.

The data storage device 120 may transmit and receive a plurality of signals Sn to and from the host 110 via the signal connector 122. The signal connector 122 may include a plurality of signal pins so that the signal connector 122 may be directly electrically connected with the host 110. That is, for example, the signal pins of the signal connector 122 are directly electrically connected with the host 110 so that the data storage device 120 may transmit and receive signals Sn to and from the host 110. The signals Sn may include a command signal, an address signal, a data signal, etc. The controller 121 may control a memory operation with respect to the plurality of non-volatile memories 128_1 through 128_n based on the signals Sn including the command signal, the address signal, the data signal, etc.

The data storage device 120 may receive power voltages Vm by being connected to a power source included in the host 110 via the power connector 126. The power connector 126 may include a plurality of power pins so that the power connector 126 may be directly electrically connected to the power source of the host 110. That is, for example, the power pins of the power connector 126 may be directly electrically connected to the power source of the host 110 so that the data storage device 120 may receive the power voltages Vm from the host 110. The power voltage transmitter 125 may transmit power voltages VI₁ through VIₖ necessary for performing a certain operation to the controller 121 and the non-volatile memories 128_1 through 128_n. According to an example embodiment, the power voltage transmitter 125 may include a plurality of conductive lines for transmitting the power voltages VI₁ through VIₖ, to the controller 121 and the non-volatile memories 128_1 through 128_n.

According to an example embodiment, the data storage device 120 may provide a hot plug function with respect to the host 110. The power voltage transmitter 125 may include a plurality of pre-charge conductive lines for suppressing and/or preventing inrush currents, which may be generated (e.g., instantly generated) when the host 110 is electrically connected to the data storage device 120 in an ‘ON’ state via the signal connector 122 and the power connector 126. The power connector 126 may further include a plurality of pre-charge pins that are electrically connected to the host 110 before the power pins, when the power connector 126 is electrically connected to the host 110. The plurality of pre-charge pins may be electrically connected to the plurality of pre-charge conductive lines of the power voltage transmitter 125, respectively, and the pre-charge pins and the pre-charge conductive lines may form a pre-charge circuit. According to an example embodiment, the pre-charge conductive lines may have a greater resistance value than other conductive lines. The pre-charge circuit may pre-charge semiconductor devices of the data storage device 120, before receiving a power voltage from the power source of the host 110. That is, for example, the pre-charge circuit may suppress and/or prevent inrush currents by pre-charging an input capacitor with respect to the semiconductor devices of the data storage device 120 by forming pre-charge current in a target range, which refers to a range of current values, which are less (e.g., quite less) than current values of the inrush currents. For example, the target range when the inrush currents correspond to 10 A may correspond to 1.5 A through 2 A, and the pre-charge current may be generated in the target range via the pre-charge circuit. However, it is only an example, and the target range may be various ranges of current values.

The pre-charge conductive line may have varying resistance values according to a magnitude of target current necessary for charging the input capacitor. For example, the pre-charge conductive line may have a decreased resistance value when the magnitude of the target current decreases. A more detailed description of this aspect will be given later.

The pre-charge circuit of the electronic device 120 receiving a power supply from the outside according to an example embodiment may more effectively suppress and/or prevent inrush currents by pre-charging the input capacitor with respect to the semiconductor devices of the electronic device 120 by using the pre-charge conductive line rather than a pre-charge resistor element, and may reduce the number of necessary components of the electronic device 120 to correspond to allow for further reduction in size and/or miniaturization of the electronic device 120.

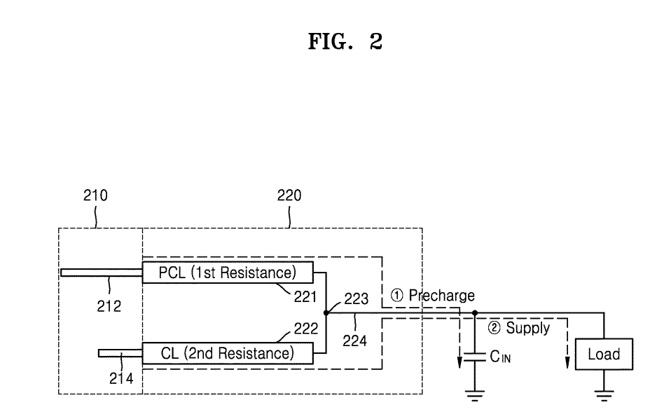

FIG. 2 is a diagram showing, in more detail, a power connector 210 and a power voltage transmitter 220 of an electronic device, according to an example embodiment.

Referring to FIG. 2, the power connector 210 may include a pre-charge pin 212 and a power pin 214. The pre-charge pin 212 according to an example embodiment may be longer than the power pin 214. Thus, when the electronic device is electrically connected to an external power source via the power connector 210, the pre-charge pin 212 may be connected to the external power source before the power pin 214. The power voltage transmitter 220 may include a pre-charge conductive line 221, a first conductive line 222, and a second conductive line 224. A node at which the pre-charge conductive line 221 and the first conductive line 223 meet may be referred to as a voltage supply node 223.

According to an example embodiment, the pre-charge conductive line 221 may be formed between the pre-charge pin 212 and the voltage supply node 223, and may electrically connect the pre-charge pin 212 to the voltage supply node 223. Also, the pre-charge conductive line 221 may have a first resistance value to generate pre-charge current necessary for a pre-charge operation performed to suppress and/or prevent inrush currents due to the external power source to which the power connector 210 is connected. The first conductive line 222 may be formed between the power pin 214 and the voltage supply node 223, and may electrically connect the power pin 214 to the voltage supply node 223. Also, the first conductive line 222 may transmit a power voltage supplied from the external power source to the voltage supply node 223 via the power pin 214, and may have a second resistance value, which is less than the first resistance value of the pre-charge conductive line 221. The second conductive line 224 may be formed between a plurality of semiconductor devices and the voltage supply node 223, and may electrically connect the plurality of semiconductor devices to the voltage supply node 223. The second conductive line 224 may transmit the power voltage to the plurality of semiconductor devices. For convenience of description, only one second conductive line 224 is illustrated, but example embodiments are not limited thereto. The power voltage transmitter 220 may include a plurality of second conductive lines 224. Further, the power voltage transmitter 220 may include a plurality of pre-charge conductive lines and a plurality of first conductive lines.

According to an example embodiment, the semiconductor devices may be included in the electronic device 120 illustrated in FIG. 1. In more detail, for example, the semiconductor devices may be included in the controller 121 and the plurality of non-volatile memories 128_1 through 128_n of FIG. 1, and the controller 121 and the plurality of non-volatile memories 128_1 through 128_n may receive the power voltage necessary for operation, via the second conductive line 224.

Hereinafter, example operations of the power connector 210 and the power voltage transmitter 220 will be described in more detail. In this example, the plurality of semiconductor devices are described as a capacitor C_{IN} and a load Load corresponding thereto, for convenience of description. The capacitor C_{IN} may be the input capacitor of the electronic device 120 of FIG. 1, and the load Load may be an input load of the electronic device 120 of FIG. 1. A pre-charge circuit including the pre-charge pin 212 and the pre-charge conductive line 221 may pre-charge the capacitor C_{IN} to suppress and/or prevent inrush currents due to the external power source. That is, for example, the pre-charge pin 212 may be electrically connected to the external power source before the power pin 214, and the pre-charge circuit may generate pre-charge current in a target range by using the pre-charge conductive line 221 having the first resistance value and the power voltage from the external power source, without including an additional, separate resistor element (e.g., between the pre-charge pin 212 and the voltage supply node 223). The pre-charge circuit may \textcircled{1} pre-charge the capacitor C_{IN} via the pre-charge current.

When the power pin 214 is electrically connected to the external power source, the capacitor C_{IN} is pre-charged, and thus, the inrush currents, which may be generated in order to charge the capacitor C_{IN}, may be suppressed and/or prevented in advance, and the power voltage may be more stably \textcircled{2} supplied to the load Load via the first conductive line 222 and the second conductive line 224. According to an example embodiment, when the pre-charge operation on the capacitor C_{IN} is complete and the power voltage is supplied to the load Load, the first resistance value of the pre-charge conductive line 221 is greater than the second resistance value of the first conductive line 222, and thus, current flowing in the pre-charge conductive line 221 may be less than current flowing in the first conductive line 222.

According to an example embodiment, at least one of a length, a width, and a conductivity of the pre-charge conductive line 221 may be different from a length, a width, and a conductivity of the first conductive line 222, so that the pre-charge conductive line 221 and the first conductive line 222 may have different resistance values. A more detailed description of this aspect will be given later.

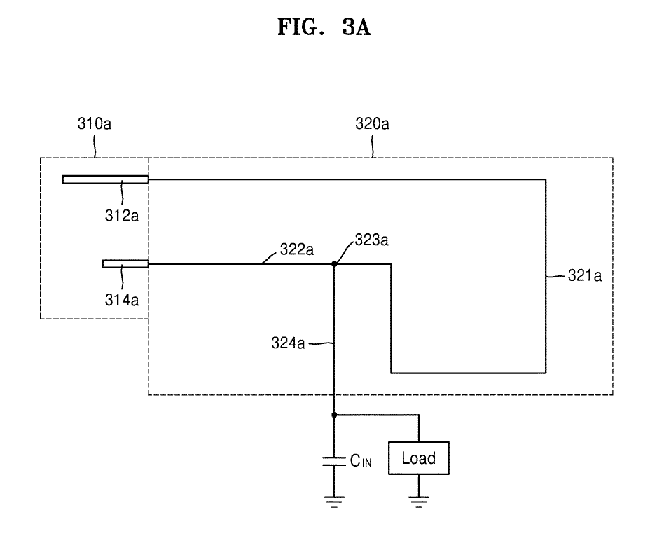

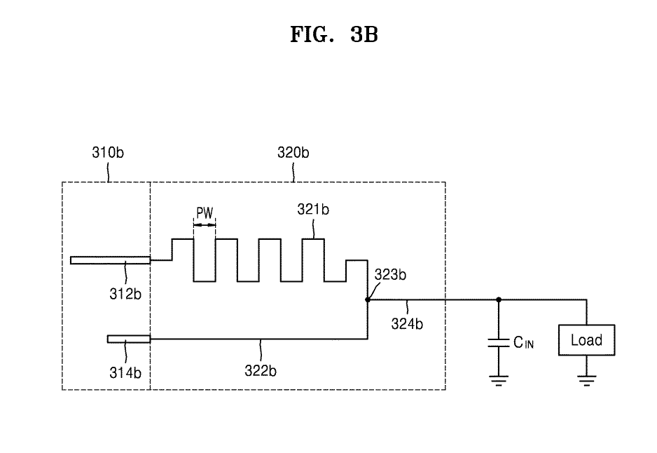

FIGS. 3A and 3B are diagrams showing more detailed structures of power voltage transmitters 320a and 320b of electronic devices, according to example embodiments.

Referring to FIG. 3A, the power voltage transmitter 320a may be electrically connected to a power connector 310a and may provide a power voltage from an external power source to an electronic device including the power voltage transmitter 320a. The power connector 310a may include a pre-charge pin 312a and a power pin 314a. The power voltage transmitter 320a may include a pre-charge conductive line 321a, a first conductive line 322a, and a second conductive line 324a. The pre-charge conductive line 321a, the first conductive line 322a, and the second conductive line 324a may meet at a power supply node 323a.

The pre-charge conductive line 321a according to an example embodiment may be formed to be longer than the first conductive line 322a while having the same or substantially the same width and/or the same or substantially the same conductivity as the first conductive line 322a. For example, the pre-charge conductive line 321a and the first conductive line 322a may be formed on an area of a circuit substrate included in the electronic device 120 of FIG. 1, except an area on which the controller 121 and the non-volatile memory devices 128_1 through 128_n are mounted. In order to generate pre-charge current in a target range necessary for a pre-charge operation on the capacitor C_{IN}, the pre-charge conductive line 321a may be formed by using an empty area of the circuit substrate. Via this structure, a resistance value of the pre-charge conductive line 321a may be greater than a resistance value of the first conductive line 322a.

A length of the pre-charge conductive line 321a may be determined by taking into account the target range of the pre-charge current necessary for the pre-charge operation on the capacitor C_{IN} of the electronic device 120 of FIG. 1, and a voltage level of the external power source to which the pre-charge pin 312a is to be connected. For example, the length of the pre-charge conductive line 321a may increase as a level of the pre-charge current necessary for the pre-charge operation on the capacitor C_{IN} decreases depending on a characteristic of the electronic device 120 of FIG. 1 or the voltage level of the external power source to which the pre-charge pin 312a is to be connected increases. Also, the length of the pre-charge conductive line 321a may decrease as the level of the pre-charge current necessary for the pre-charge operation on the capacitor C_{IN} increases depending on the characteristic of the electronic device 120 of FIG. 1 or the voltage level of the external power source to which the pre-charge pin 312a is to be connected decreases.

In FIG. 3B, descriptions will be given by focusing on a different structure from FIG. 3A.

Referring to FIG. 3B, the power voltage transmitter 320b may be electrically connected to a power connector 310b. The power connector 310b may include a pre-charge pin 312b and a power pin 314b. A pre-charge conductive line 321b of the power voltage transmitter 320b according to an example embodiment may be formed on a circuit substrate to have a pattern of repeated quadrangular shapes, compared to a first conductive line 322b formed in a straight line. The pre-charge conductive line 321b, the first conductive line 322b, and a second conductive line 324b are connected to one another at a power supply node 323b.

In this example embodiment, a width and a conductivity of the pre-charge conductive line 321b may be the same or substantially the same as a width and/or a conductivity of the first conductive line 322b. Via this structure, a resistance value of the pre-charge conductive line 321b may be greater than a resistance value of the first conductive line 322b. According to an example embodiment, a pattern width PW of the pre-charge conductive line 321b may be determined by taking into account the target range of pre-charge current necessary for a pre-charge operation on the capacitor C_{IN} of the electronic device 120 of FIG. 1 and a voltage level of an external power source to which the pre-charge pin 312b is to be connected. For example, the pattern width PW of the pre-charge conductive line 321b may decrease as a level of the pre-charge current necessary for the pre-charge operation on the capacitor C_{IN} decreases depending on a characteristic of the electronic device 120 of FIG. 1 or the voltage level of the external power source to which the pre-charge pin 312b is to be connected increases. Also, the pattern width PW of the pre-charge conductive line 321b may increase as the level of the pre-charge current necessary for the pre-charge operation on the capacitor C_{IN} increases depending on the characteristic of the electronic device 120 of FIG. 1 or the voltage level of the external power source to which the pre-charge pin 312b is to be connected decreases. However, the pattern of repeated quadrangular shapes of the pre-charge conductive line 321b is only an example, and the pre-charge conductive line 321b may have a pattern of various repeated shapes, such as a pattern of repeated triangular shapes, circular shapes, zigzag shapes, or spiral shapes. Via this, an area of the circuit substrate, necessary for forming the pre-charge conductive line 321b of FIG. 3B may be less than an area of the circuit substrate, necessary for forming the pre-charge conductive line 321a of FIG. 3A, and thus, the circuit substrate may be more efficiently used.

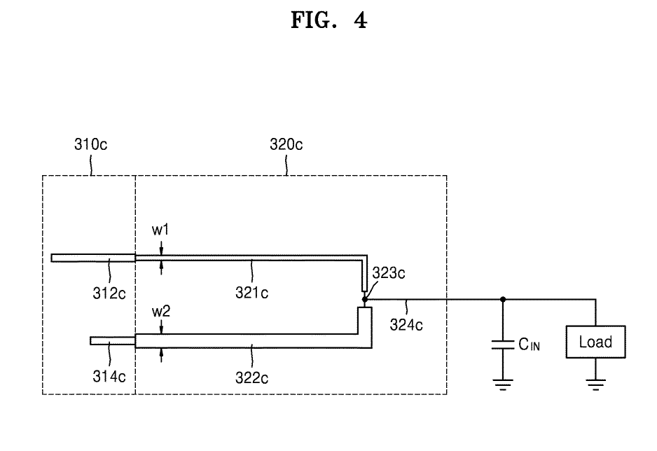

FIG. 4 is a diagram showing a detailed structure of a power voltage transmitter 320c, according to another example embodiment.

In FIG. 4, descriptions will be given by focusing on a different structure from FIG. 3A.

Referring to FIG. 4, the power voltage transmitter 320c may be electrically connected to a power connector 310c. The power connector 310c may include a pre-charge pin 312c and a power pin 314c. A width w1 of a pre-charge conductive line 321c, according to an example embodiment, may be less than a width w2 of a first conductive line 322c. The pre-charge conductive line 321c, the first conductive line 322c, and a second conductive line 324c are connected to one another at a power supply node 323c.

In this example, a length and/or a conductivity of the pre-charge conductive line 321c may be the same or substantially the same as a length and/or a conductivity of the first conductive line 322c. Via this structure, a resistance value of the pre-charge conductive line 321c may be greater than a resistance value of the first conductive line 322c. According to an example embodiment, the width W1 of the pre-charge conductive line 321c may be determined by taking into account a target range of pre-charge current necessary for a pre-charge operation on the capacitor C_{IN} of the electronic device 120 of FIG. 1 and a voltage level of an external power source to which the pre-charge pin 312c is to be connected. For example, the width w1 of the pre-charge conductive line 321c may decrease as a level of the pre-charge current necessary for the pre-charge operation on the capacitor C_{IN} decreases depending on a characteristic of the electronic device 120 of FIG. 1 or the voltage level of the external power source to which the pre-charge pin 312c is to be connected increases. Also, the width w1 of the pre-charge conductive line 321c may increase as the level of the pre-charge current necessary for the pre-charge operation on the capacitor CN increases depending on the characteristic of the electronic device 120 of FIG. 1 or the voltage level of the external power source to which the pre-charge pin 312a is to be connected decreases.

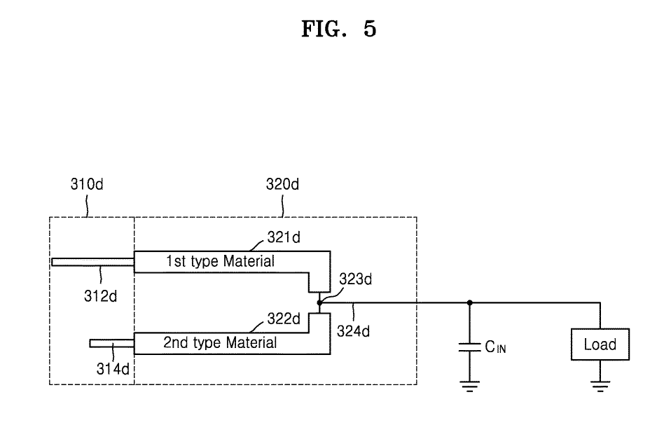

FIG. 5 is a diagram showing a more detailed structure of a power voltage transmitter 320d, according to another example embodiment.

In FIG. 5, descriptions will be given by focusing on a different structure from FIG. 3A.

Referring to FIG. 5, the power voltage transmitter 320d may be electrically connected to a power connector 310d. The power connector 310d may include a pre-charge pin 312d and a power pin 314d. A conductivity of a pre-charge conductive line 321d, according to an example embodiment, may be greater than a conductivity of a first conductive line 322d. The pre-charge conductive line 321d, the first conductive line 322d, and a second conductive line 324d are connected to one another at a power supply node 323d.

According to an example embodiment, the pre-charge conductive line 321d may include a first type material, and the first conductive line 322d may include a second type material. The first type material may have a greater conductivity than the second type material. For example, the first type material may include aluminum (Al), zinc (Zn), etc., and the second type material may include gold (Au), silver (Ag), copper (Cu), etc. Also, the first type material and the second type material may include an alloy including two types or more than two types of gold. Via this structure, a resistance value of the pre-charge conductive line 321d may be greater than a resistance value of the first conductive line 322d.

According to an example embodiment, the conductivity of the pre-charge conductive line 321d may be determined by taking into account a target range of pre-charge current necessary for a pre-charge operation on the capacitor C_{IN} of the electronic device 120 of FIG. 1 and a voltage level of an external power source to which the pre-charge pin 312d is to be connected. For example, the conductivity of the pre-charge conductive line 321d may decrease as a level of the pre-charge current necessary for the pre-charge operation on the capacitor C_{IN} decreases depending on a characteristic of the electronic device 120 of FIG. 1 or the voltage level of the external power source to which the pre-charge pin 312d is to be connected increases. Also, the conductivity of the pre-charge conductive line 321d may increase as the level of the pre-charge current necessary for the pre-charge operation on the capacitor Cm increases depending on the characteristic of the electronic device 120 of FIG. 1 or the voltage level of the external power source to which the pre-charge pin 312d is to be connected decreases. To this end, the first conductive material included in the pre-charge conductive line 321d may vary according to the determined conductivity of the pre-charge conductive line 321d.

In FIGS. 3A through 5, it is described that any one of the length, the width, or the conductivity of the pre-charge conductive line is different from the length, the width, or the conductivity of the first conductive line. However, example embodiments are not limited thereto, and at least two of the length, the width, and the conductivity of the pre-charge conductive line may be different from the length, the width, and the conductivity of the first conductive line.

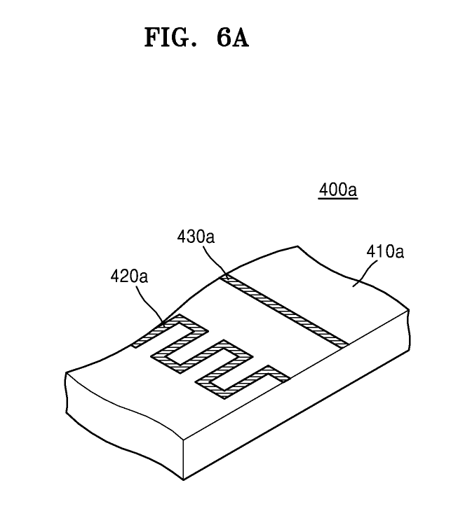

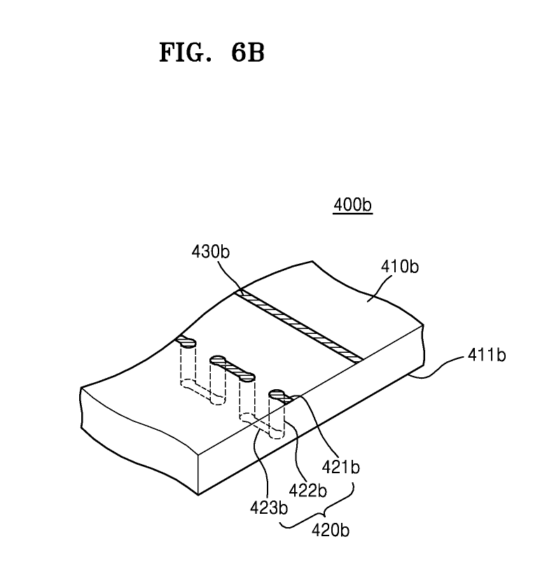

FIGS. 6A and 6B are three-dimensional views of circuit substrates 400a and 400b included in the electronic device 120, according to an example embodiment.

Referring to FIGS. 1 and 6A, a pre-charge conductive line 420a and a first conductive line 430a may be formed on a surface 410a of the circuit substrate 400a included in the electronic device 120. That is, for example, as described above, the pre-charge conductive line 420a may be formed on the surface 410a of the circuit substrate 400a to have a resistance value greater than the first conductive line 430a.

Referring to FIG. 6B, a first conductive line 430b may be formed on a surface 410b of the circuit substrate 400b. Unlike FIG. 6A, however, a pre-charge conductive line 420b may be formed on a surface 410b and the other surface 411b of the circuit substrate 400b. That is, for example, the pre-charge conductive line 420b may include a first conductive pattern 421b formed on the surface 410b, a penetration via 422b penetrating the circuit substrate 400b, and a second conductive pattern 423b formed on the other surface 411b. Via this structure, an area of the circuit substrate 400b, on which the pre-charge conductive line 420b is formed, may be less than the case of FIG. 6A. Further, via this structure, the first conductive pattern 421b and the second conductive pattern 423b of the pre-charge conductive line 420b may have a different conductivity from the penetration via 422b. For example, the penetration via 422b may have less conductivity than the first conductive pattern 421b and the second conductive pattern 423b so that the pre-charge conductive line 420b according to an example embodiment may have a greater resistance value than the first conductive line 430b.

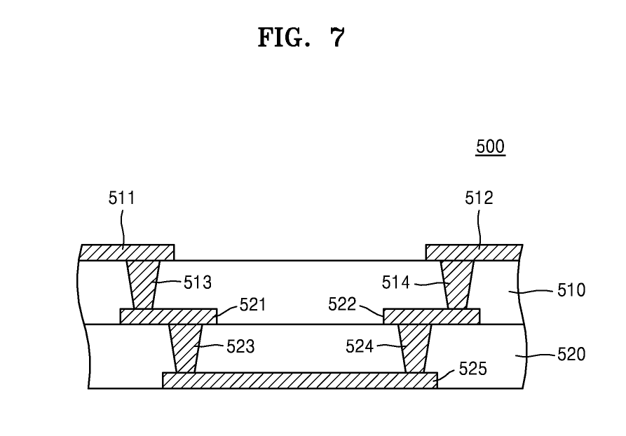

FIG. 7 is a cross-sectional view of a multi-layered circuit substrate 500 included in the electronic device 120, according to another example embodiment.

Referring to FIG. 7, the multi-layered circuit substrate 500 included in the electronic device 120 of FIG. 1, according to this example embodiment, may be the multi-layered circuit substrate 500. The multi-layered circuit substrate 500 may be a coreless multi-layered circuit substrate including two layered insulating layers. According to an example embodiment, a pre-charge conductive line may be formed on the multi-layered circuit substrate 500, wherein the pre-charge conductive line includes a plurality of conductive patterns formed on each of the insulating layers and a plurality of penetration vias penetrating each of the insulating layers. That is, for example, the multi-layered circuit substrate 500 may include a first insulating layer 510 and a second insulating layer 520. The pre-charge conductive line may include first conductive patterns 511 and 512 formed on an upper surface of the first insulating layer 510, second conductive patterns 521 and 522 formed at a boundary between the first insulating layer 510 and the second insulating layer 520, a third conductive pattern 525 formed at a lower surface of the second insulating layer 520, first penetration vias 513 and 514 penetrating the first insulating layer 510 and electrically connected to the first conductive patterns 511 and 512 and the second conductive patterns 521 and 522, and second penetration vias 523 and 524 penetrating the second insulating layer 520 and electrically connected to the second conductive patterns 521 and 522 and the third conductive pattern 525. According to an example embodiment, the first penetration vias 513 and 514 may have a different conductivity from the first conductive patterns 511 and 512 or the second conductive patterns 521 and 522.

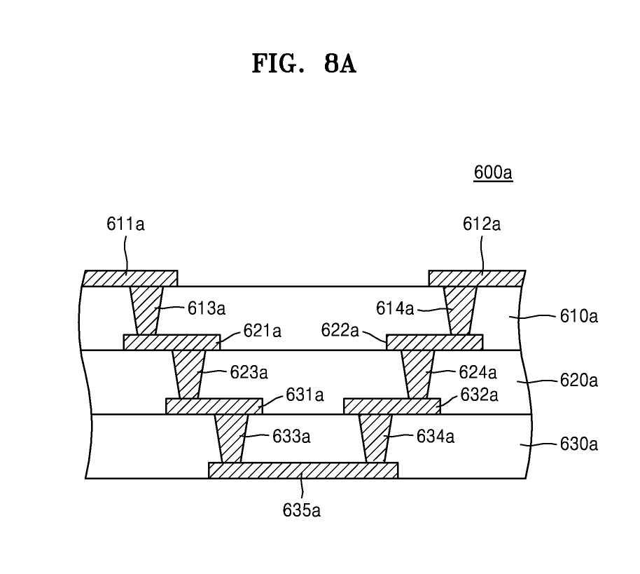

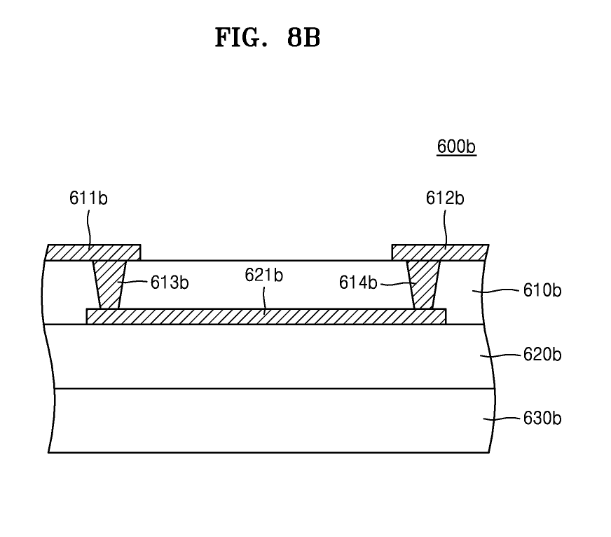

FIGS. 8A and 8B are cross-sectional views of multi-layered circuit substrates 600a and 600b included in the electronic device 120, according to another example embodiment.

Referring to FIG. 8A, the multi-layered circuit substrate 600a included in the electronic device 120 of FIG. 1, according to this example embodiment, may be the multi-layered circuit substrate 600a. FIG. 8A illustrates an example of a pre-charge conductive line formed on the multi-layered circuit substrate 600a. The multi-layered circuit substrate 600a may be a coreless multi-layered circuit substrate including three layered insulating layers. The multi-layered circuit substrate 600a may include a first insulating layer 610a, a second insulating layer 620a, and a third insulating layer 630a. The pre-charge conductive line may include first conductive patterns 611a and 612a formed on an upper surface of the first insulating layer 610a, second conductive patterns 621a and 622a formed at a boundary between the first insulating layer 610a and the second insulating layer 620a, third conductive patterns 631a and 632a formed at a boundary between the second insulating layer 620a and the third insulating layer 630a, a fourth conductive pattern 635a formed at a lower surface of the third insulating layer 630a, first penetration vias 613a and 614a penetrating the first insulating layer 610a and electrically connected to the first conductive patterns 611a and 612a and the second conductive patterns 621a and 622a, second penetration vias 623a and 624a penetrating the second insulating layer 620a and electrically connected to the second conductive patterns 621a and 622a and the third conductive patterns 631a and 632a, and third penetration vias 633a and 634a penetrating the third insulating layer 630a and electrically connected to the third conductive patterns 631a and 632a and the fourth conductive pattern 635a.

Referring to FIG. 8B, an example of a first conductive line formed on the multi-layered circuit substrate 600b is illustrated. The first conductive line may include first conductive patterns 611b and 612b formed on an upper surface of a first insulating layer 610b, a second conductive pattern 621b formed at a boundary between the first insulating layer 610b and a second insulating layer 620b, and first penetration vias 613b and 614b penetrating the first insulating layer 610b and electrically connected to the first conductive patterns 611b and 612b and the second conductive pattern 621b. The second insulating layer 620b may be on a third insulating layer 630b. The first conductive line may include a lesser number of penetration vias than the pre-charge conductive line of FIG. 8A. Also, the first conductive line may include a lesser number of conductive patterns than the pre-charge conductive line of FIG. 8A.

Via this structure, the pre-charge conductive line of FIG. 8A may have a greater resistance value than the first conductive line. However, the structures illustrated in FIGS. 8A and 8B are only an example, and example embodiments are not limited thereto. The pre-charge conductive line and the first conductive line may vary.

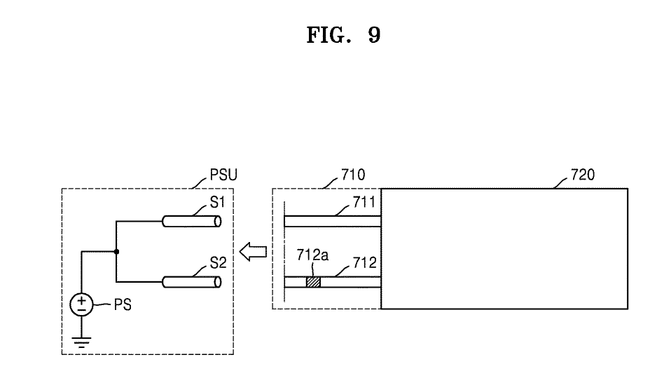

FIG. 9 is a diagram of a power connector 710 included in an electronic device, according to an example embodiment.

Referring to FIG. 9, the power connector 710 may include a pre-charge pin 711 and a power pin 712. The pre-charge pin 711 may be electrically connected to a pre-charge conductive line of a power voltage transmitter 720, and the power pin 712 may be electrically connected to a first conductive line of the power voltage transmitter 720. The power connector 710 may be electrically connected to a power source unit PSU to supply a power voltage to the electronic device. The power source unit PSU may include a power source PS, a first socket S1 electrically connected to the pre-charge pin 711, and a second socket S2 electrically connected to the power pin 712. According to an example embodiment, the pre-charge pin 711 may have the same or substantially the same length as the power pin 712. The power pin 712 may include a non-conductive area 712a. Thus, although the pre-charge pin 711 and the power pin 712 have the same or substantially the same lengths, the pre-charge pin 711 may be electrically connected to the power source unit PSU before the power pin 712. A size and a location of the non-conductive area 712a included in the power pin 712 may vary.

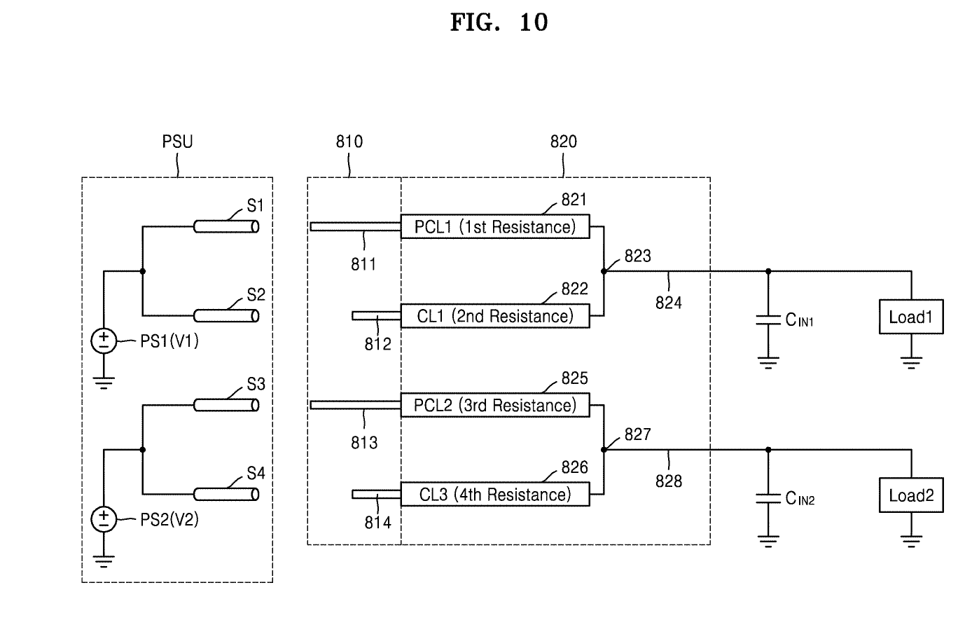

FIG. 10 is a diagram showing, in more detail, a power connector 810 and a power voltage transmitter 820 of an electronic device, according to another example embodiment.

Referring to FIG. 10, the power connector 810 may include a first pre-charge pin 811, a first power pin 812, a second pre-charge pin 813, and a second power pin 814. The first pre-charge pin 811, according to an example embodiment, may be longer than the first power pin 812 and the second pre-charge pin 813 may be longer than the second power pin 814. However, it is only an example embodiment, and the structure of the power pin 712 of FIG. 9 may be applied to the first and second power pins 812 and 814 of FIG. 10. The power connector 810 may be electrically connected to a power source unit PSU. The power source unit PSU may include a first power source PS1, a first socket S1 and a second socket S2 electrically connected to the first power source PS1, a second power source PS2, and a third socket S3 and a fourth socket S4 electrically connected to the second power source PS2. The first pre-charge pin 811 and the first power pin 812 may be electrically connected to the first socket S1 and the second socket S2, respectively, and may receive a first power voltage V1 via a first power source PS1. The second pre-charge pin 813 and the second power pin 814 may be electrically connected to the third socket S3 and the fourth socket S4, respectively, and may receive a second power voltage V2 via a second power source PS2.

The power voltage transmitter 820 may include a first pre-charge conductive line 821, a first conductive line 822, a second conductive line 824, a second pre-charge conductive line 825, a third conductive line 826, and a fourth conductive line 828. The first pre-charge conductive line 821 may be formed between the first pre-charge pin 811 and a first voltage supply node 823, and may electrically connect the first pre-charge pin 811 to the first voltage supply node 823. The first pre-charge conductive line 821 may be formed to have a first resistance value to generate first pre-charge current necessary for a pre-charge operation performed to suppress and/or prevent inrush currents due to the first power source PS1. The first conductive line 822 may transmit the first power voltage V1 supplied from the first power source PS1 to the first voltage supply node 823 via the first power pin 812 and may be formed to have a second resistance value, which is less than the first resistance value of the first pre-charge conductive line 821. The second conductive line 824 may be formed between a plurality of first semiconductor devices and the first voltage supply node 823 and may electrically connect the plurality of first semiconductor devices to the first voltage supply node 823. The second conductive line 824 may transmit the first power voltage V1 to the first semiconductor devices. For convenience of description, the plurality of first semiconductor devices are illustrated as a first capacitor C_{IN1} and a first load Load1 corresponding thereto.

The second pre-charge conductive line 825 may be formed between the second pre-charge pin 813 and a second voltage supply node 827 and may electrically connect the second pre-charge pin 813 to the second voltage supply node 827. The second pre-charge conductive line 825 may be formed to have a third resistance value to generate second pre-charge current necessary for a pre-charge operation performed to suppress and/or prevent inrush currents due to a second power source PS2. The third conductive line 826 may transmit a second power voltage V2 supplied from the second power source PS2 to the second voltage supply node 827 via the second power pin 814, and may be formed to have a fourth resistance value, which is less than the third resistance value of the second pre-charge conductive line 825. The fourth conductive line 828 may be formed between a plurality of second semiconductor devices and the second voltage supply node 827 and may electrically connect the plurality of second semiconductor devices to the second voltage supply node 827. The fourth conductive line 828 may transmit the second power voltage V2 to the second semiconductor devices. For convenience of description, the plurality of second semiconductor devices are illustrated as a second capacitor C_{IN2} and a second load Load2.

According to an example embodiment, the first resistance value of the first pre-charge conductive line 821 and the third resistance value of the second pre-charge conductive line 825 may be different from each other. A magnitude of the second power source PS2 may be greater than a magnitude of the first power source PS1. In this case, the first resistance value of the first pre-charge conductive line 821 may be less than the third resistance value of the second pre-charge conductive line 825. Via this, when the pre-charge operation is performed on the first capacitor C_{IN1} and the second capacitor C_{IN2}, first pre-charge current for pre-charging the first capacitor C_{IN1} and second pre-charge current for pre-charging the second capacitor C_{IN2} may be in the same or substantially the same target range. That is, for example, the first resistance value of the first pre-charge conductive line 821 electrically connected to the first power source PS1, which is less than the second power source PS2 may be less than the second resistance value of the second pre-charge conductive line 825 electrically connected to the second power source PS2, so that the first pre-charge current and the second pre-charge current may be in the same or substantially the same target range.

According to an example embodiment, at least one of a length, a width, or a conductivity of the first pre-charge conductive line 821 may be different from at least one of a length, a width, or a conductivity of the second pre-charge conductive line 825, so that the first pre-charge conductive line 821 and the second pre-charge conductive line 825 may have different resistance values. Also, the structure illustrated in FIG. 10 is only an example, and example embodiments are not limited thereto. The power source unit PSU may include more power sources than the power source unit PSU illustrated in FIG. 10, and the power connector 810 may include more pre-charge pins and power pins than the power connector 810 illustrated in FIG. 10. Thus, the power voltage transmitter 820 may include more conductive lines than the power voltage transmitter 820 illustrated in FIG. 10. Detailed descriptions of this aspect will be given later.

Also, the relationship between the first pre-charge conductive line 821 and the first conductive line 822, and the relationship between the second pre-charge conductive line 825 and the third conductive line 826 are described in detail with reference to FIGS. 1 through 9, and thus, will not be repeatedly described here.

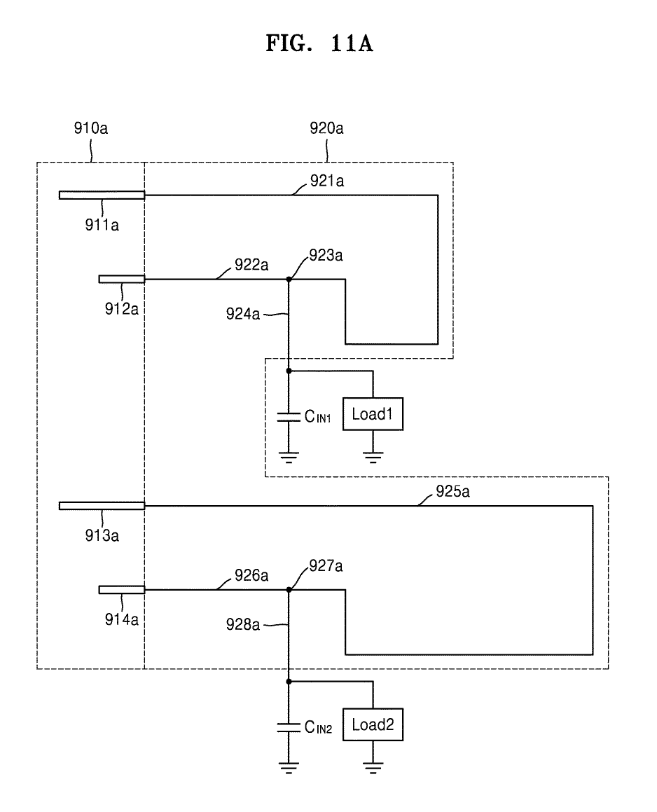

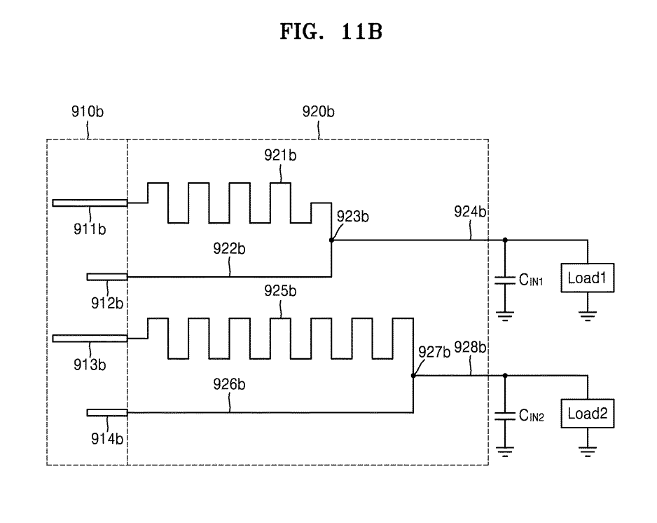

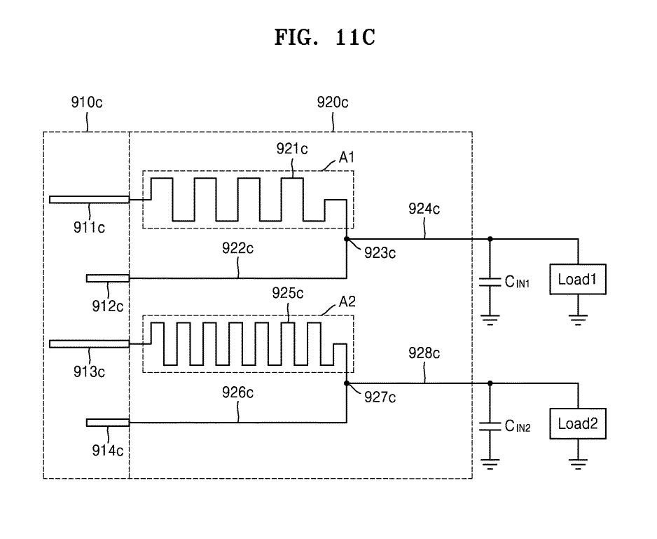

FIGS. 11A through 11C are diagrams showing more detailed structures of power voltage transmitters 920a, 920b, and 920c of an electronic device, according to an example embodiment.

Referring to FIG. 11A, the power voltage transmitter 920a may be electrically connected to a power connector 910a and may provide a power voltage from an external power source to the electronic device including the power voltage transmitter 920a. The power connector 910a may include a first pre-charge pin 911a, a first power pin 912a, a second pre-charge pin 913a, and a second power pin 914a. As in FIG. 10, the first pre-charge pin 911a and the first power pin 912a may be electrically connected to a first power source PS1, and the second pre-charge pin 913a and the second power pin 914a may be electrically connected to a second power source PS2.

The power voltage transmitter 920a may include a first pre-charge conductive line 921a, a first conductive line 922a, a second conductive line 924a, a second pre-charge conductive line 925a, a third conductive line 926a, and a fourth conductive line 928a. The first pre-charge conductive line 921a, the first conductive line 922a, and the second conductive line 924a may meet one another at a first power supply node 923a. The second pre-charge conductive line 925a, the third conductive line 926a, and the fourth conductive line 928a may meet one another at a second power supply node 927a. Hereinafter, it is assumed that a magnitude of the second power source PS2 is greater than a magnitude of the first power source PS1.

The second pre-charge conductive line 925a according to an example embodiment may be formed to be longer on a circuit substrate included in the electronic device than the first pre-charge conductive line 921a, while having the same or substantially the same width and/or the same or substantially the same conductivity as the first pre-charge conductive line 921a. Via this, a resistance value of the second pre-charge conductive line 925a may be greater than a resistance value of the first pre-charge conductive line 921a.

In FIG. 11B, descriptions will be given by focusing on a different structure from FIG. 11A.

Referring to FIG. 11B, a power voltage transmitter 920b may be electrically connected to a power connector 910b and may provide a power voltage from an external power source to the electronic device including the power voltage transmitter 920b. The power connector 910b may include a first pre-charge pin 911b, a first power pin 912b, a second pre-charge pin 913b, and a second power pin 914b.

The power voltage transmitter 920b may include a first pre-charge conductive line 921b, a first conductive line 922b, a second conductive line 924b, a second pre-charge conductive line 925b, a third conductive line 926b, and a fourth conductive line 928b. The first pre-charge conductive line 921b, the first conductive line 922b, and the second conductive line 924b may meet one another at a first power supply node 923b. The second pre-charge conductive line 925b, the third conductive line 926b, and the fourth conductive line 928b may meet one another at a second power supply node 927b.

The second pre-charge conductive line 925b according to an example embodiment may be formed on a circuit substrate to have a greater number of patterns having repeated quadrangular shapes than the first pre-charge conductive line 921b. Via this structure, a resistance value of the second pre-charge conductive line 925b may be greater than a resistance value of the first pre-charge conductive line 921b.

In FIG. 11C, descriptions will be given by focusing on a different structure from FIG. 11B.

Referring to FIG. 11C, a power voltage transmitter 920c may be electrically connected to a power connector 910c and may provide a power voltage from an external power source to the electronic device including the power voltage transmitter 920c. The power connector 910c may include a first pre-charge pin 911c, a first power pin 912c, a second pre-charge pin 913c, and a second power pin 914c.

The power voltage transmitter 920c may include a first pre-charge conductive line 921c, a first conductive line 922c, a second conductive line 924c, a second pre-charge conductive line 925c, a third conductive line 926c, and a fourth conductive line 928c. The first pre-charge conductive line 921c, the first conductive line 922c, and the second conductive line 924c may meet one another at a first power supply node 923c. The second pre-charge conductive line 925c, the third conductive line 926c, and the fourth conductive line 928c may meet one another at a second power supply node 927c.

The second pre-charge conductive line 925c according to an example embodiment may have a narrower pattern width than the first pre-charge conductive line 921c. Via this, a size of an area A2 of a circuit substrate, on which the second pre-charge conductive line 925c is formed, may be the same or substantially the same as a size A1 of an area of the circuit substrate, on which the first pre-charge conductive line 921c is formed. Via this, the first pre-charge conductive line 921c and the second pre-charge conductive line 925c may be formed on the circuit substrate efficiently in terms of space.

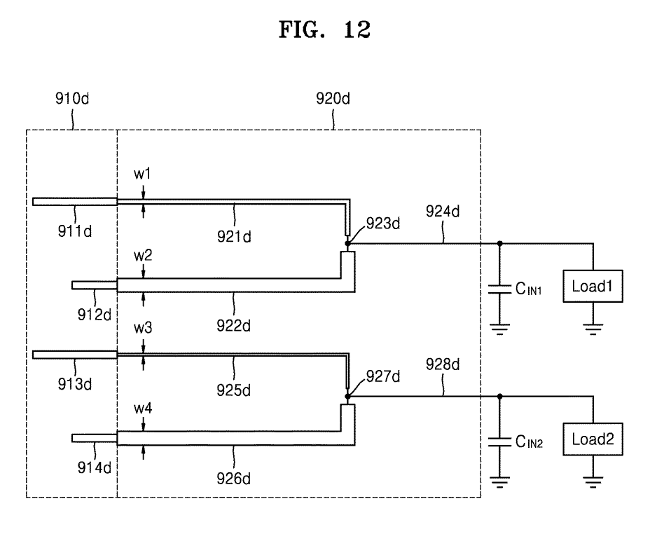

FIG. 12 is a diagram showing a more detailed structure of a power voltage transmitter 920d of an electronic device, according to another example embodiment.

In FIG. 12, descriptions will be given by focusing on a different structure from FIG. 11A.

Referring to FIG. 12, the power voltage transmitter 920d may be electrically connected to a power connector 910d and may provide a power voltage from an external power source to the electronic device including the power voltage transmitter 920d. The power connector 910d may include a first pre-charge pin 911d, a first power pin 912d, a second pre-charge pin 913d, and a second power pin 914d.

The power voltage transmitter 920d may include a first pre-charge conductive line 921d, a first conductive line 922d, a second conductive line 924d, a second pre-charge conductive line 925d, a third conductive line 926d, and a fourth conductive line 928d. The first pre-charge conductive line 921d, the first conductive line 922d, and the second conductive line 924d may meet one another at a first power supply node 923d. The second pre-charge conductive line 925d, the third conductive line 926d, and the fourth conductive line 928d may meet one another at a second power supply node 927d.

The second pre-charge conductive line 925d according to an example embodiment may have the same or substantially the same length and/or the same or substantially the same conductivity as the first pre-charge conductive line 921d, while having a width w3, which is less than a width w4 of the third conductive line 926d and a width w1 of the first pre-charge conductive line 921d. Via this structure, a resistance value of the second pre-charge conductive line 925d may be greater than a resistance value of the first pre-charge conductive line 921d.

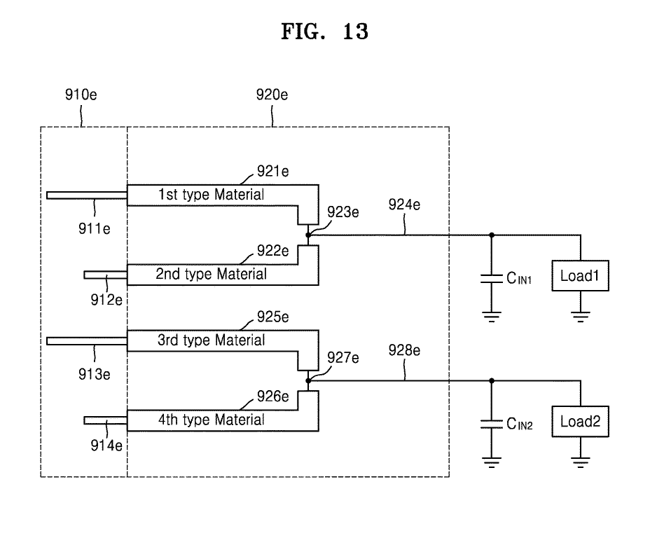

FIG. 13 is a diagram showing a more detailed structure of a power voltage transmitter 920e of an electronic device, according to another example embodiment.

In FIG. 13, descriptions will be given by focusing on a different structure from FIG. 11A.

Referring to FIG. 13, the power voltage transmitter 920e may be electrically connected to a power connector 910e and may provide a power voltage from an external power source to the electronic device including the power voltage transmitter 920e. The power connector 910e may include a first pre-charge pin 911e, a first power pin 912e, a second pre-charge pin 913e, and a second power pin 914e.

The power voltage transmitter 920e may include a first pre-charge conductive line 921e, a first conductive line 922e, a second conductive line 924e, a second pre-charge conductive line 925e, a third conductive line 926e, and a fourth conductive line 928e. The first pre-charge conductive line 921e, the first conductive line 922e, and the second conductive line 924e may meet one another at a first power supply node 923e. The second pre-charge conductive line 925e, the third conductive line 926e, and the fourth conductive line 928e may meet one another at a second power supply node 927e.

The second pre-charge conductive line 925e according to an example embodiment may have the same or substantially the same length and/or the same or substantially the same width as the first pre-charge conductive line 921e, while having less conductivity than the first pre-charge conductive line 921e. That is, for example, the second pre-charge conductive line 925e may include a third type material, and the first pre-charge conductive line 921e may include a first type material having greater conductivity than the third type material. Via this structure, a resistance value of the second pre-charge conductive line 925e may be greater than a resistance value of the first pre-charge conductive line 921e.

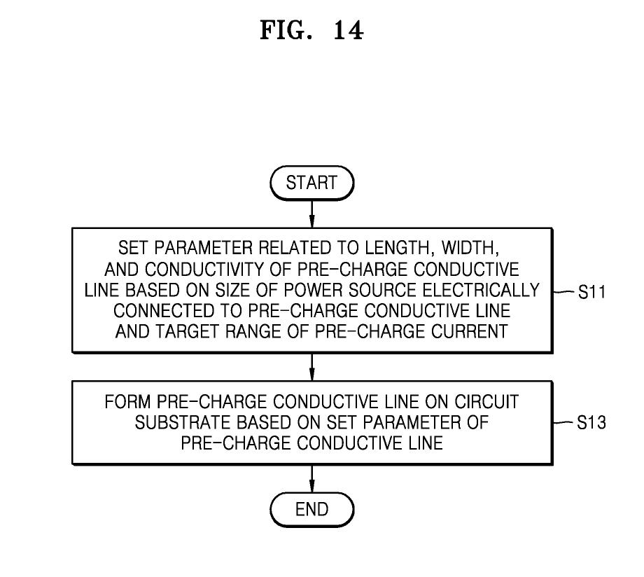

FIG. 14 is a flowchart of a method of forming a pre-charge conductive line on a circuit substrate, according to an example embodiment.

Referring to FIG. 14, a parameter related to a length, a width, and a conductivity of the pre-charge conductive line may be set based on a magnitude of a power source electrically connected to the pre-charge conductive line and a target range of pre-charge current, in operation S11.

Based on the set parameter of the pre-charge conductive line, the pre-charge conductive line having a greater resistance value than a first conductive line is formed on a circuit substrate, in operation S13. As such, the pre-charge conductive line may be formed in various ways by taking into account the magnitude of the power source electrically connected to the pre-charge conductive line and the target range of the pre-charge current.

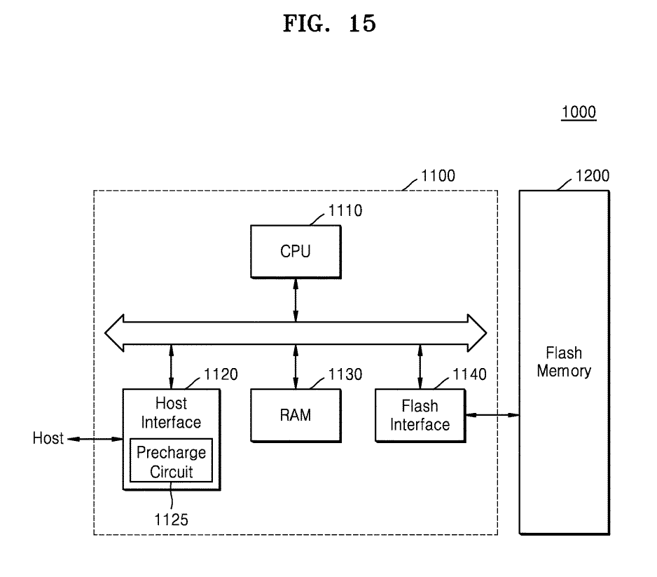

FIG. 15 is a block diagram of an example of a data storage device 1000, according to an example embodiment.

Referring to FIG. 15, the data storage device 1000 may include a flash memory 1200 and a memory controller 1100. The memory controller 1100 may control the flash memory 1200. RAM 1130 may be used as working memory of a central processing unit (CPU) 1110. A host interface 1120 may include a data exchange protocol of a host connected to the data storage device 1000. Also, according to an example embodiment, the host interface 1120 may include a pre-charge circuit 1125 according to the example embodiments of FIGS. 1 through 14. The pre-charge circuit 1125 may include a pre-charge pin and a pre-charge conductive line electrically connected to the pre-charge pin. According to an example embodiment, when the data storage device 1000 is connected to a power source of the host (e.g., during a hot plug operation), the pre-charge circuit 1125 may pre-charge semiconductor devices in the data storage device 1000 in order to suppress and/or prevent inrush currents due to the power source of the host. The pre-charge circuit 1125 according to an example embodiment may generate pre-charge current in a target range, which is necessary for pre-charging the semiconductor devices in the data storage device 1000 by using a pre-charge conductive line having a certain resistance value, rather than using a resistor element. Via this structure, the number of elements necessary for the data storage device 1000 may be reduced, and thus, size of the data storage device 1000 may be reduced.

A flash interface 1140 may interface with the flash memory 120, and the CPU 1110 may perform general control operations for data exchange of the memory controller 1100.

According to at least some example embodiments, memories discussed herein may be embodied to include a three dimensional (3D) memory array. The 3D memory array may be monolithically formed on a substrate (e.g., semiconductor substrate such as silicon, or semiconductor-on-insulator substrate). The 3D memory array may include two or more physical levels of memory cells having an active area disposed above the substrate and circuitry associated with the operation of those memory cells, whether such associated circuitry is above or within such substrate. The layers of each level of the array may be directly deposited on the layers of each underlying level of the array. In example embodiments, the 3D memory array may include VNAND strings that are vertically oriented such that at least one memory cell is located over another memory cell. The at least one memory cell may comprise a charge trap layer.

The following patent documents, which are hereby incorporated by reference in their entirety, describe suitable configurations for three-dimensional memory arrays, in which the three-dimensional memory array is configured as a plurality of levels, which word lines and/or bit lines shared between levels: U.S. Pat. Nos. 7,679,133; 8,553,466; 8,654,587; 8,559,235; and U.S. Patent Application Publication No. 2011/0233648.

As is traditional in the field of inventive concepts, some embodiments (e.g., controllers, source voltage transmission units, hosts, etc.) may be described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of inventive concepts. Further, the blocks, units and/or modules of the embodiments may be physically combined into more complex blocks, units and/or modules without departing from the scope of inventive concepts.

While inventive concepts have been particularly shown and described with reference to example embodiments thereof, it will be understood that various changes in form and details may be made therein without departing from the spirit and scope of the following claims.

1. An electronic device comprising:
a plurality of semiconductor devices;
a connector including a pre-charge pin and a power pin;
a pre-charge conductive line configured to electrically connect the pre-charge pin to a voltage supply node, the pre-charge conductive line having a first resistance value configured to generate pre-charge current for a pre-charge operation on the plurality of semiconductor devices, the pre-charge current performed to prevent inrush currents due to an external power source;
a first conductive line having a second resistance value, the first conductive line configured to electrically connect the power pin to the voltage supply node, and to transmit a power voltage to the voltage supply node from the external power source, the second resistance value less than the first resistance value; and
a second conductive line configured to electrically connect the plurality of semiconductor devices to the voltage supply node, and to transmit the power voltage to the plurality of semiconductor devices.

2. The electronic device of claim 1, wherein the pre-charge pin is configured to electrically connect to the external power source before the power pin when the electronic device is electrically connected to the external power source via the connector.

3. The electronic device of claim 2, wherein the pre-charge pin is longer than the power pin.

4. The electronic device of claim 2, wherein
the pre-charge pin has a same length as the power pin, and
the power pin includes a non-conductive area.

5. The electronic device of claim 1, wherein the pre-charge conductive line has a length greater than a length of the first conductive line.

6. The electronic device of claim 1, wherein the pre-charge conductive line has a width less than a width of the first conductive line.

7. The electronic device of claim 1, wherein the pre-charge conductive line has a conductivity less than a conductivity of the first conductive line.

8. The electronic device of claim 1, wherein
the electronic device further includes a circuit substrate;
the pre-charge conductive line includes
a first conductive pattern on a first surface of the circuit substrate,
a second conductive pattern on a second surface of the circuit substrate, and
a penetration via structure electrically connecting the first conductive pattern to the second conductive pattern; and
the first conductive line includes a third conductive pattern on the first surface of the circuit substrate.

9. The electronic device of claim 1, wherein
the electronic device further includes a multi-layered circuit substrate;
the pre-charge conductive line includes
a plurality of first conductive patterns on the multi-layered circuit substrate, and
a plurality of first penetration vias; and
the first conductive line includes
a plurality of second conductive patterns on the multi-layered circuit substrate, and
a plurality of second penetration vias.

10. The electronic device of claim 9, wherein a number of first penetration vias in the plurality of first penetration vias is greater than a number of second penetration vias in the plurality of second penetration vias.

11. The electronic device of claim 1, wherein the first resistance value of the pre-charge conductive line varies according to a magnitude of the power voltage from the external power source.

12. A pre-charge circuit, comprising:
a first pre-charge pin electrically connected to a first external power source;
a second pre-charge pin electrically connected to a second external power source;
a first pre-charge conductive line configured to electrically connect the first pre-charge pin to a first voltage supply node, the first pre-charge conductive line having a first resistance value configured to generate first pre-charge current for a first pre-charge operation on at least one first semiconductor device receiving a first power voltage via the first voltage supply node; and
a second pre-charge conductive line configured to electrically connect the second pre-charge pin to a second voltage supply node, the second pre-charge conductive line having a second resistance value to generate second pre-charge current for a second pre-charge operation on at least one second semiconductor device receiving a second power voltage via the second voltage supply node.

13. The pre-charge circuit of claim 12, wherein the first resistance value is greater than the second resistance value when a first voltage of the first voltage supply node is greater than a second voltage of the second voltage supply node.

14. The pre-charge circuit of claim 12, wherein the first pre-charge conductive line and the second pre-charge conductive line are different from each other in at least one of a line length, a line width, or a conductivity.

15. The pre-charge circuit of claim 12, wherein a magnitude of the first pre-charge current and a magnitude of the second pre-charge current are in a same target range when the pre-charge circuit performs at least one of the first and second pre-charge operations.

16. An electronic device, comprising:
a power connector including a pre-charge pin and a power supply pin;
a power supply conductive line configured to electrically connect the power supply pin to a power supply node, the power supply conductive line having a first resistance; and
a pre-charge conductive line configured to electrically connect the pre-charge pin to the power supply node without an intervening resistor between the pre-charge pin and the power supply node, the pre-charge conductive line having a second resistance, the second resistance greater than the first resistance.

17. The electronic device of claim 16, further comprising:
at least one semiconductor device; and
a conductive line electrically connecting the at least one semiconductor device to the power supply node.

18-20. (canceled)

21. The electronic device of claim 16, wherein the pre-charge conductive line and the power supply conductive line have at least one of different lengths, different widths, or different conductivities.

22. The electronic device of claim 16, wherein the pre-charge conductive line electrically connects the pre-charge pin directly to the power supply node.

23. The electronic device of claim 16, wherein
the power supply conductive line has a first conductive pattern structure;
the pre-charge conductive line has a second conductive pattern structure; and
the first conductive pattern structure is different from the second conductive pattern structure.
